(19) United States
(12) Patent Application Publication
(10) Pub. No.: US 2023/0005870 A1
(43) Pub. Date: Jan. 5, 2023

(54) 3D PRINTED INTERCONNECTS AND RESONATORS FOR SEMICONDUCTOR DEVICES

(71) Applicant: MACOM Technology Solutions Holdings, Inc., Lowell, MA (US)

(72) Inventors: Rathnait Long, Lowell, MA (US); Wayne Struble, Lowell, MA (US); Douglas Carlson, Lowell, MA (US)

(21) Appl. No.: 17/364,930

(22) Filed: Jul. 1, 2021

(51) Int. Cl. H01L 23/00; B33Y 10/00; B33Y 80/00; B22F 10/10

(52) U.S. Cl. CPC H01L 24/13; H01L 24/05; H01L 24/11; B33Y 10/00; B33Y 80/00; B22F 10/10; H01L 2224/13012; H01L 2224/13014; H01L 2224/13144; H01L 2224/13124; H01L 2224/13147; H01L 2224/13181; H01L 2224/13157; H01L 2224/13176; H01L 2224/13166; H01L 2224/13111; H01L 2224/13139; H01L 2224/0401; H01L 2224/05644; H01L 2224/05624; H01L 2224/05647; H01L 2224/05684; H01L 2224/05681; H01L 2224/05639; H01L 2224/05664; H01L 2224/11318; B22F 10/85

(57) ABSTRACT

Techniques regarding forming flip chip interconnects are provided. For example, one or more embodiments described herein can comprise a three-dimensionally printed flip chip interconnect that includes an electrically conductive ink material that is compatible with a three-dimensional printing technology. The three-dimensionally printed flip chip interconnect can be located on a metal surface of a semiconductor chip.

### BACKGROUND

The subject disclosure relates to three-dimensionally (“3D”) printed features of a semiconductor device, and more specifically, to 3D printing techniques that can form interconnects for flip chip assemblies and/or tune resonators of a semiconductor device.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, methods, apparatuses and/or devices that can employ 3D printing to achieve and/or modify one or more features of a semiconductor device are described.

According to an embodiment, a device is provided. The device can comprise a three-dimensionally printed flip chip interconnect that can include an electrically conductive ink material that is compatible with a three-dimensional printing technology. The three-dimensionally printed flip chip interconnect can be located on a metal surface of a semiconductor chip.

According to an embodiment, a method is provided. The method can comprise forming a flip chip interconnect by depositing an electrically conductive ink material onto a chip pad of a semiconductor device. The depositing can be performed via a three-dimensional printing technology.

According to an embodiment, a method is provided. The method can comprise tuning a resonator of a semiconductor device by depositing an ink material onto a surface of the resonator. The depositing can be performed via a three-dimensional printing technology.

### BRIEF DESCRIPTION OF THE DRAWINGS

FIG. 1A illustrates a diagram of an example, non-limiting cross-sectional view of a 3D printed interconnect that can be employed in a flip chip assembly in accordance with one or more embodiments described herein.

FIG. 1B illustrate a diagram of an example, non-limiting cross-sectional view of a flip chip assembly that can include one or more 3D printed interconnects in accordance with one or more embodiments described herein.

FIG. 2 illustrates a diagram of an example, non-limiting top-down view of example geometries that can be embodied by one or more 3D printed interconnects, which can be employed in a flip chip assembly in accordance with one or more embodiments described herein.

FIG. 3 illustrates a diagram of an example, non-limiting cross-sectional view of a 3D printed interconnect during a first stage of manufacturing in accordance with one or more embodiments described herein.

FIGS. 4A-4D illustrate diagrams of an example, non-limiting 3D printed interconnect during a second stage of manufacturing in accordance with one or more embodiments described herein.

FIGS. 5A-C illustrate diagrams of an example, non-limiting 3D printed interconnect during a third stage of manufacturing in accordance with one or more embodiments described herein.

FIGS. 6A-B illustrate diagrams of example, non-limiting top-down views of one or more 3D printed interconnects that can be employed in a flip chip assembly in accordance with one or more embodiments described herein.

FIG. 7 illustrates a diagram of an example, non-limiting printing map that can be generated to facilitate 3D printing one or more structures in accordance with one or more embodiments described herein.

FIG. 8 illustrates a diagram of an example, non-limiting cross-sectional view of a resonator of a semiconductor device tuned via one or more 3D printing technologies in accordance with one or more embodiments described herein.

FIG. 9 illustrates a diagram of an example, non-limiting cross-sectional view of a resonator of a semiconductor device during a first stage of tuning in accordance with one or more embodiments described herein.

FIGS. 10A-D illustrates a diagram of an example, non-limiting cross-sectional view of a resonator of a semiconductor device during a second stage of tuning in accordance with one or more embodiments described herein.

FIGS. 11A-C illustrate diagrams of an example, non-limiting 3D printed interconnect during a third stage of tuning in accordance with one or more embodiments described herein.

FIG. 12 illustrates a flow diagram of an example, non-limiting method that can facilitate manufacturing one or more 3D printed interconnects that can be employed in a flip chip assembly in accordance with one or more embodiments described herein.

FIG. 13 illustrates a flow diagram of an example, non-limiting method that can facilitate tuning one or more resonators of a semiconductor device via one or more 3D printing technologies in accordance with one or more embodiments described herein.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details. Additionally, features depicted in the drawings with like shading, cross-hatching, and/or coloring can comprise shared compositions and/or materials.

Flip chip assemblies can be employed to connect one or more semiconductor devices (e.g., integrated circuit chips, integrated passive devices, microelectrochemical systems, and/or the like) with external circuitry (e.g., a package assembly). The one or more semiconductor devices can be positioned on one or more first chips, while the external circuitry can be positioned on one or more second chips. The first chip can further comprise one or more chip pads, which can be align with one or more chip pads on the second chip. An electrically conductive material can be deposited onto the chip pads. When the first chip is placed on the second chip, the electrically conductive material can contact the aligned chip pads of the first and second chips to establish an interconnect.

Typically, the electrically conductive material is deposited onto the chip pads as multi-layered pillars or stud bumps. However, formation of multi-layered pillars requires full wafer processing and numerous processing steps that may impair, damage, and/or inhibit one or more features of the flip chip assembly. Additionally, control over the dimensions and/or geometry of stud bumps can be substantially limited. For example, the top surface of the stud bumps includes a neck portion formed from disrupting the flow of deposited material, where the dimensions and/or geometry of the neck portion can vary with each implementation.

Various embodiments described herein can regard the use of 3D printing technology to form one or more flip chip interconnects and/or tune one or more resonators of a semiconductor device. In one or more embodiments, 3D printed interconnects can be printed directly onto one or more chip pads. Further, the 3D printing technology employed to form the interconnects can enable the formation of precisely defined sizes and/or geometries. In one or more embodiments, one or more resonators of a semiconductor device can be tuned via the one or more 3D printing technologies. For example, material can be added to a surface of the one or more resonators to alter the operating frequency exhibited by the one or more resonators.

As described herein, the terms “deposition process” and/or “deposition processes” can refer to any process that grows, coats, deposits, and/or otherwise transfers one or more first materials onto one or more second materials. Example deposition processes can include, but are not limited to: physical vapor deposition (“PVD”), chemical vaper deposition (“CVD”), electrochemical deposition (“ECD”), atomic layer deposition (“ALD”), low-pressure chemical vapor deposition (“LPCVD”), plasma enhanced chemical vapor deposition (“PECVD”), high density plasma chemical vapor deposition (“HDPCVD”), sub-atmospheric chemical vapor deposition (“SACVD”), rapid thermal chemical vapor deposition (“RTCVD”), in-situ radical assisted deposition, high temperature oxide deposition (“HTO”), low temperature oxide deposition (“LTO”), limited reaction processing CVD (“LRPCVD”), ultrahigh vacuum chemical vapor deposition (“UHVCVD”), metalorganic chemical vapor deposition (“MOCVD”), physical vapor deposition (“PVD”), chemical oxidation, sputtering, plating, evaporation, spin-on-coating, ion beam deposition, electron beam deposition, laser assisted deposition, chemical solution deposition, a combination thereof, and/or the like.

As described herein, the terms “lithography process” and/or “lithography processes” can refer to the formation of three-dimensional relief images or patterns on a semiconductor substrate for subsequent transfer of the pattern to the substrate. In semiconductor lithography, the patterns can be formed by a light sensitive polymer called a photo-resist. To build the complex structures that make up a semiconductor device and the many wires that connect the various features of a circuit, lithography processes and/or etch pattern transfer steps can be repeated multiple times. Each pattern being printed on the wafer can be aligned to the previously formed patterns and slowly the subject features (e.g., conductors, insulators and/or selectively doped regions) can be built up to form the final device.

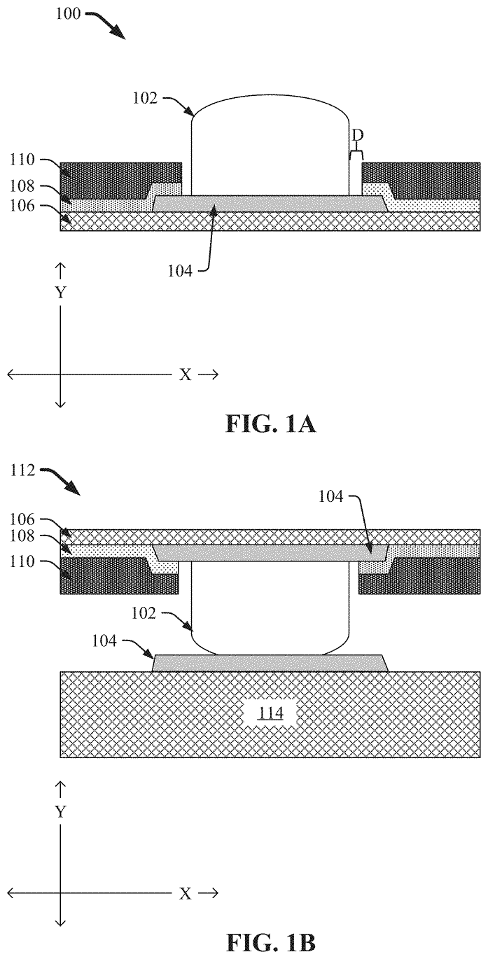

FIG. 1A illustrates a diagram of an example, non-limiting cross-sectional view of a chip structure 100 comprising one or more interconnects 102 that can be 3D printed and/or employed within one or more flip chip assemblies in accordance with one or more embodiments described herein. Repetitive description of like elements employed in other embodiments described herein is omitted for the sake of brevity. As shown in FIG. 1A, the one or more interconnects 102 can be positioned on one or more chip pads 104 of the chip structure 100. Further, the one or more chip pads 104 can be positioned on one or more semiconductor substrates 106. Additionally, the one or more interconnects 102 can be at least partially surrounded by one or more layers such as: one or more intermediary layers 108 and/or passivation layers 110.

The semiconductor substrate 106 can be crystalline, semi-crystalline, microcrystalline, or amorphous. The semiconductor substrate 106 can comprise essentially (e.g., except for contaminants) a single element (e.g., silicon or germanium) and/or a compound (e.g., aluminum oxide, silicon dioxide, gallium arsenide, silicon carbide, silicon germanium, a combination thereof, and/or the like). The semiconductor substrate 106 can also have multiple material layers, such as, but not limited to: a semiconductor-on-insulator substrate (“SeOI”), a silicon-on-insulator substrate (“SOI”), germanium-on-insulator substrate (“GeOI”), silicon-germanium-on-insulator substrate (“SGOI”), a combination thereof, and/or the Ike, Additionally, the semiconductor substrate 106 can also have other layers, such as oxides with high dielectric constants (“high-K oxides”) and/or nitrides, hi one or more embodiments, the semiconductor substrate 106 can be a silicon wafer. In various embodiments, the semiconductor substrate 106 can comprise a single crystal silicon (Si), silicon germanium (e.g., characterized by the chemical formula SiGe), a Group III-V semiconductor wafer or surface/active layer, a combination thereof, and/or the like.

The one or more chip pads 104 can be one or more metal surfaces. Example metals that can comprise the one or more chip pads 104 can include, but are not limited to: gold, aluminum, copper, tungsten, tantalum, silver, palladium, a combination thereof, and/or the like. In one or more embodiments, the one or more chip pads 104 can have a circular or polygonal shape. For instance, the one or more chip pads 104 can have a rectangular shape (e.g., as shown in FIG. 1A). The one or more chip pads 104 can have a total thickness (e.g., along the Y axis shown in FIG. 1A) ranging from, for example, greater than or equal to 0.1 micrometers (μm) and less than or equal to 6 μm. The one or more chip pads 104 can have a width (e.g., along the X axis shown in FIG. 1) ranging from, for example, greater than or equal to 30 μm and less than or equal to 300 μm. A shown in FIG. 1A, the one or more chip pads 104 can be located on the semiconductor substrate 106.

As shown in FIG. 1A, one or more intermediary layers 108 and/or passivation layers 110 can also be positioned on the semiconductor substrate 106. Additionally, the one or more intermediary layers 108 and/or passivation layers 110 can be positioned on at least a portion of the one or more chip pads 104. In various embodiments, the one or more intermediary layers 108 can be metal or dielectrics. Example materials that can comprise the one or more intermediary layers 108 can include, but are not limited to: silicon nitride (S₃N₄), aluminum nitride (AlN), benzocyclobutene (BCB), aluminum oxide (Al₂O₃), a combination thereof, and/or the like. Further, the one or more intermediary layers 108 can have a thickness (e.g., along the Y axis shown in FIG. 1A) ranging from, for example, greater than or equal to 0.05 μm and less than or equal to 8 μm. In various embodiments, the one or more passivation layers 110 can protect one or more surfaces of the chip structure 100 from the surrounding environment. Example materials that can comprise the one or more passivation layers 110 can include, but are not limited to: silicon nitride (S₃N₄), aluminum nitride (AlN), benzocyclobutene (BCB), aluminum oxide (Al₂O₃), a combination thereof, and/or the like. Further, the one or more passivation layers 110 can have a thickness (e.g., along the Y axis shown in FIG. 1A) ranging from, for example, greater than or equal to 0.05 μm and less than or equal to 8 μm. In various embodiments, the one or more intermediary layers 108 and/or passivation layers 110 can be distanced from the one or more interconnects 102 by a distance “D” ranging from, for example, greater than or equal to 0.05 μm and less than or equal to 8 μm.

In one or more embodiments, the one or more interconnects 102 can be printed onto the one or more chip pads 104 via one or more 3D printing technologies. For example, the one or more interconnects 102 can comprise one or more electrically conductive ink material compatible with one or more 3D printing technologies. For example, the electrically conductive ink material can comprise one or more metals including, but not limited to: gold, aluminum, copper, tantalum, cobalt, ruthenium, titanium, tin silver, solder, an alloy thereof, a combination thereof, and/or the like. In one or more embodiments, the one or more interconnects 102 can have a substantially homogenous composition (e.g., as shown in FIG. 1A). In one or more embodiments, the one or more interconnects 102 can comprise multiple types of electrically conductive ink materials (e.g., arranged in a stacked orientation to form a multi-layered interconnect).

The one or more interconnects 102 can have a thickness (e.g., along the Y axis shown in FIG. 1A) ranging from, for example, greater than or equal to 20 μm and less than or equal to 150 μm. Additionally, the one or more interconnects 102 can have a width (e.g., along the X axis shown in FIG. 1A) ranging from, for example, greater than or equal to 20 μm and less than or equal to 200 μm. In various embodiments, the geometry of the one or more interconnects 102 can vary depending on the application and/or desired physical properties of the one or more interconnects 102. While FIG. 1A depicts the one or more interconnects 102 with a substantially cylindrical shape, the architecture of the one or more interconnects 102 is not so limited. For instance, the one or more interconnects 102 can have a spherical shape, a cuboid shape, a pyramid shape, a prism shape, a polyhedron shape, a combination thereof, and/or the like. In one or more embodiments, a top surface of the one or more interconnects 102 can have a convex shape (e.g., as shown in FIG. 1A), a concave shape, a flat shape, and/or a combination thereof.

FIG. 1B illustrates a diagram of the example, non-limiting chip structure 100 employed in an example flip chip assembly 112 in accordance with one or more embodiments described herein. Repetitive description of like elements employed in other embodiments described herein is omitted for the sake of brevity. As shown in FIG. 1B, the one or more interconnects 102 can be positioned between aligned chip pads 104, respectively positioned on adjacent chips of an example flip chip assembly 112.

The chip structure 100 shown in FIG. 1A can be included in one or more first semiconductor chips and/or second semiconductor chips of the example flip chip assembly 112. For example, the chip structure 100 can be comprised within a chip that further includes one or more semiconductor devices of the example flip chip assembly 112. Example semiconductor devices can include, but are not limited to: a bulk acoustic wave device, a monolithic microwave integrated circuit, an integrated circuit, a passive integrated circuit, a microelectrochemical systems, a magnetic materials based circuit, a combination thereof, and/or the like. For instance, the chip structure 100 can be comprised within a chip that further includes one or more semiconductor features including, but not limited to: resonators, resistors, capacitors, inductors, a combination thereof, and/or the like. In another example, the chip structure 100 can be comprised within a chip that further includes one or more external circuitry of the example flip chip assembly 112.

For instance, FIG. 1B depicts an exemplary embodiment in which the chip structure 100 can be comprised within a first chip (e.g., further comprising one or more semiconductor devices) of the example flip chip assembly 112. Additionally, a second chip of the example flip chip assembly can comprise a printed circuit board 114 and/or one or more additional chip pads 104. As shown in FIG. 1B, the one or more interconnects 102 can be positioned between the respective chip pads 104 of the first and second chips when the chips are brought together to form the example flip chip assembly 112.

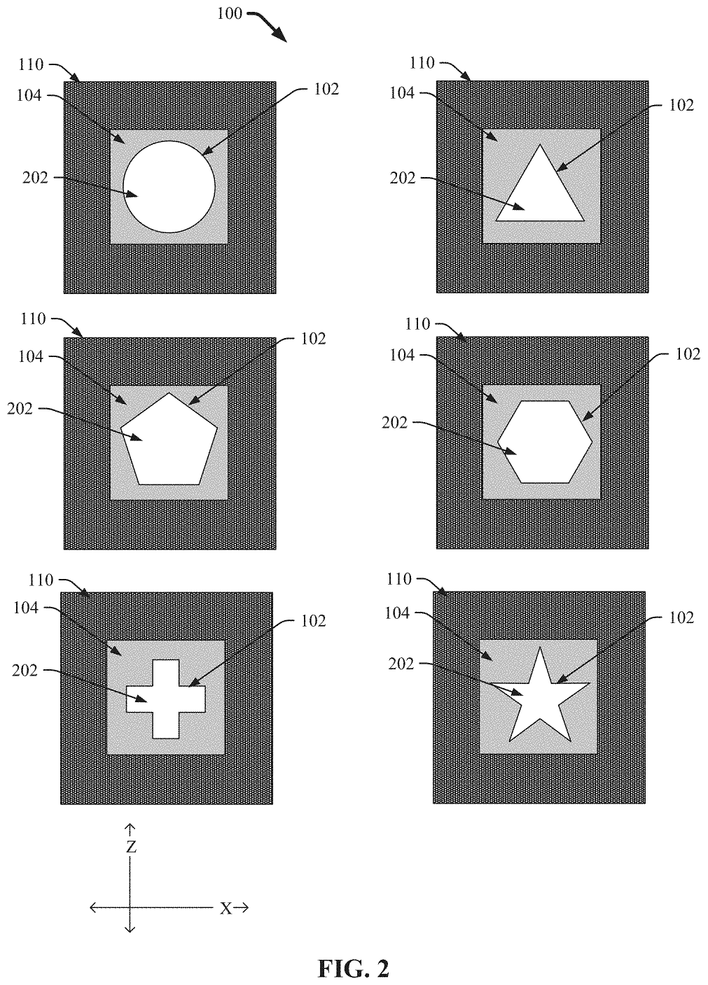

FIG. 2 illustrates a diagram of example, non-limiting top-down views of various geometries that can be embodied by the one or more interconnects 102 in accordance with one or more embodiments described herein. Repetitive description of like elements employed in other embodiments described herein is omitted for the sake of brevity. FIG. 2 shows a top surface 202 of the one or more interconnects 102 exemplified in FIG. 1A. For instance, example geometries of the distal end of the one or more interconnects 102 shown in FIG. 1A are shown in FIG. 2.

As shown in FIG. 2, the top surface 202 of the one or more interconnects 102 can have a variety of geometries depending on the desired application and/or properties of the one or more interconnects 102. For example, the top surface 202 can have, but is not limited to: a circular shape, a triangular shape, a pentagon shape, a hexagon shape, a cross shape, a star shape, a polygon shape, a combination thereof, and/or the like. In various embodiments, the shape of the top surface 202 can affect the amount of surface area of the one or more interconnects 102 that can be contacted with one or more other chip pads 104. Thereby, the shape of the top surface 202 can affect the electrical connection between chips coupled together by the one or more interconnects 102 (e.g., can affect the electrical connection between the chips of the example flip chip assembly 112 shown in FIG. 1B). For example, interconnects 102 having top surfaces 202 with larger surface areas can minimize electrical resistances and/or inductances to ground. However, special constraints on the one or more chips of the chip assembly 112 can affect the possible size of the interconnects. Various embodiments described herein can enable various interconnect 102 shapes and/or geometries to manage the relationship between increased surface area and special constraints on the one or more chips.

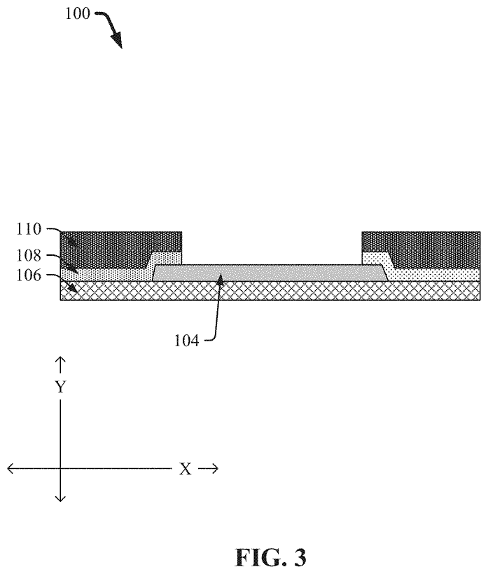

FIG. 3 illustrates a diagram of the example, non-limiting chip structure 100 during a first stage of manufacturing in accordance with one or more embodiments described herein. Repetitive description of like elements employed in other embodiments described herein is omitted for the sake of brevity. During the first stage of manufacturing, the one or more chip pads 104 can be provided and/or prepared for subsequent printing of the one or more interconnects 102.

In various embodiments, the one or more chip pads 104 can be formed on one or more targeted locations of the semiconductor substrate 106 via one or more deposition processes. Additionally, the one or more intermediary layers 108 and/or passivation layers 110 can be formed on the semiconductor substrate 106 and/or portions of the chip pads 104. Further, the one or more intermediary layers 108 and/or passivation layers 110 can be patterned via one or more lithography processes to expose at a portion of the one or more chip pads 104 for subsequent positioning of the one or more interconnects 102. Thereby, the one or more chip pads 104 can be provided for formation of the one or more interconnects 102.

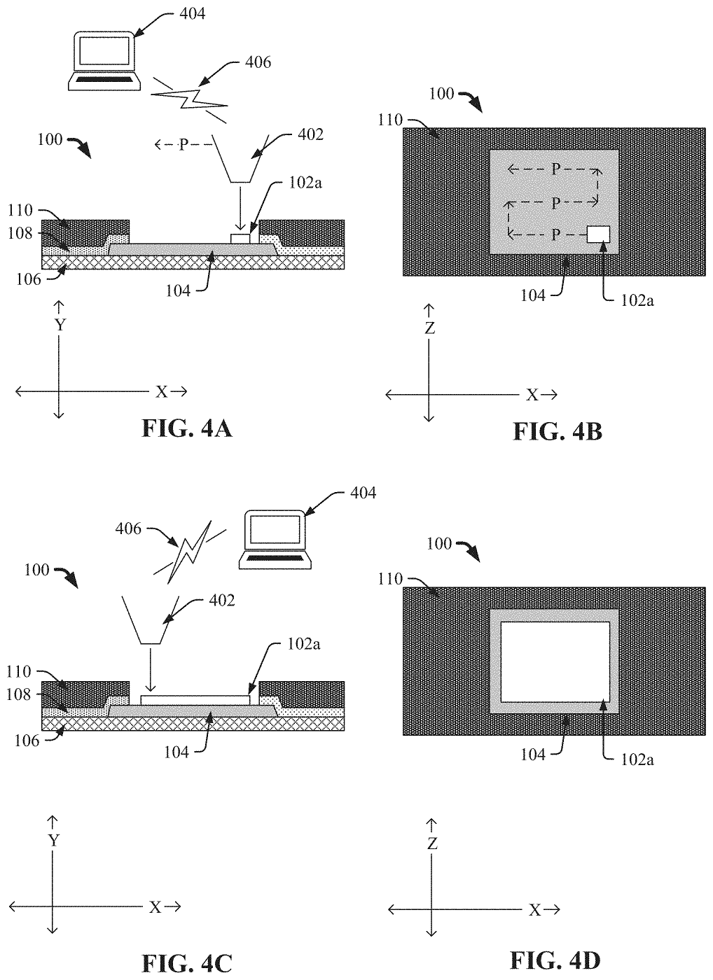

FIGS. 4A-4D illustrate diagrams of the example, non-limiting chip structure 100 during a second stage of manufacturing in accordance with one or more embodiments described herein. Repetitive description of like elements employed in other embodiments described herein is omitted for the sake of brevity. During the second stage of manufacturing, the one or more interconnects 102 can be printed onto the one or more chip pads 104 via one or more 3D printing technologies. As a result of the second stage of manufacturing, at least a first portion 102a of the one or more interconnects 102 can be formed on the one or more chip pads 104.

In various embodiments, the 3D printing technologies can deposit ink material (e.g., electrically conductive ink material) of the one or more interconnects 102 onto the one or more chip pads 104. For instance, the one or more 3D printing technologies can print the one or more interconnects 102 via an additive process, where ink material (e.g., electrically conductive ink material) can be deposited via successive layers positioned on top of each other repetitively until the desired 3D shape is achieved. Example 3D printing technologies that can be employed to print the one or more interconnects 102 can include, but are not limited to: a direct write printing technology, an inkjet printing technology, an aerosol jet printing technology, a combination thereof, and/or the like.

For example, FIGS. 4A and 4C depict an example nozzle 402 of the 3D printing technology. The electrically conductive ink material that comprises the one or more interconnects 102 can be expelled from the nozzle 402 when executing the 3D printing technology. For instance, FIGS. 4A and 4C depict ink material (e.g., electrically conductive ink material) being expelled from the example nozzle 402 and onto the one or more chip pads 104. As shown in FIGS. 4A-4B, the example nozzle 402 can travel along a printing direction (e.g., represented by arrow “P” in FIGS. 4A-4B). As the example nozzle 402 travels along the printing direction (e.g., represented by arrow “P”), the nozzle 402 can also be depositing the ink material (e.g., electrically conductive ink material) onto the one or more chip pads 104.

FIG. 4A depicts the nozzle 402 at a first position above the chip pad 104 during execution of the 3D printing technology. From the first position, the nozzle 402 can move along the printing direction (e.g., represented by arrow “P”) to a second position depicted in FIG. 4C. As shown in FIG. 4B, the printing direction (e.g., represented by arrow “P”) can traverse the one or more chip pads 104 along the X axis, the Z axis, and/or combinations thereof. Further, the printing direction can follow a straight line, a curved line, a wavy line, a combination thereof and/or the like. Thereby, the printing direction (e.g., represented by arrow “P”) can traverse through an area on the one or more chip pads 104 to be occupied by the one or more interconnects 102. Further, the path of the printing direction (e.g., represented by arrow “P”) can be defined by the geometry of the one or more interconnects 102. Therefore, the location and/or path of the printing direction (e.g., represented by arrow “P”) can be based on the desired geometry of the one or more interconnects 102. For example, the path of the printing direction (e.g., represented by arrow “P”) shown in FIG. 4B can be employed to print a rectangular prism and/or cuboid geometry of the one or more interconnects 102.

As the nozzle 402 traverses the printing direction (e.g., represented by arrow “P”), the ink material (e.g., electrically conductive ink material) can be deposited onto the one or more chip pads 104. For example, FIGS. 4C-4D depict the first portion 102a of the one or more interconnects 102 formed from the example nozzle 402 traversing the exemplary printing direction (e.g., represented by arrow “P”) shown in FIG. 4B. Additionally, although FIGS. 4C-4D illustrate a continuous, or near continuous, deposition of ink material (e.g., electrically conductive ink material) onto the chip pad 104 along the printing direction (e.g., represented by arrow “P”); the architecture of the 3D printing is not so limited. For example, embodiments in which the ink material (e.g., electrically conductive ink material) is deposited periodically (e.g., in accordance with one or more scheduled intervals) are also envisaged.

In various embodiments, the one or more example nozzles 402 of the one or more printing technologies can be controlled via one or more computer devices 404 via one or more communication connections 406 (e.g., direct electrical connections and/or wireless connections). The one or more communication connections 406 can comprise wired and wireless networks, including, but not limited to, a cellular network, a wide area network (WAN) (e.g., the Internet) or a local area network (LAN). For example, the one or more computer devices 404 can communicate with the equipment of the 3D printing technology using virtually any desired wired or wireless technology including for example, but not limited to: cellular, WAN, wireless fidelity (Wi-Fi), Wi-Max, WLAN, Bluetooth technology, a combination thereof, and/or the like.

Example computer devices 404 can include, but are not limited to: personal computers, desktop computers, laptop computers, cellular telephones (e.g., smart phones), computerized tablets (e.g., comprising a processor), smart watches, keyboards, touch screens, mice, a combination thereof, and/or the like. The one or more computer devices 404 can be employed to facilitate execution of the one or more printing technologies. For instance, the one or more computer devices 404 can send data and/or otherwise control equipment of the one or more 3D printing technologies to define the type of ink material to be used and/or the one or more printing directions to be traversed by the nozzle 402.

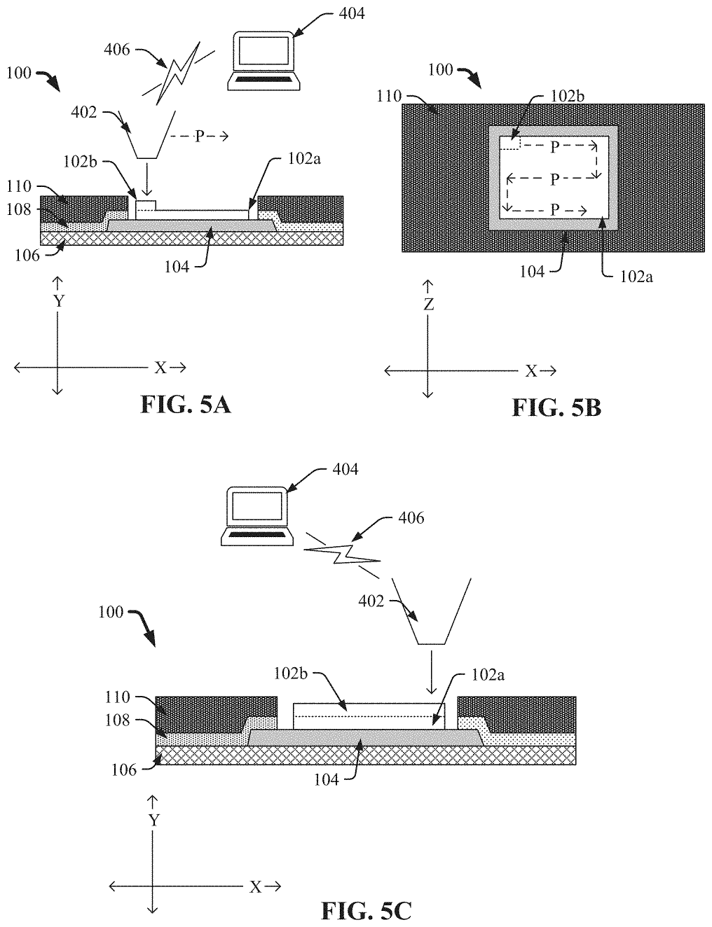

In various embodiments, the one or more computer devices 404 and/or communication connections 406 can be employed to define the location, size, shape, and/or geometry of the one or more 3D structures to be printed by the one or more 3D printing technologies (e.g., define the location, size, shape, and/or geometry of the one or more interconnects 102). For instance, the one or more computer devices 404 can execute 3D printing software to define one or more printing directions that can be employed during the second and/or third stage of manufacturing (e.g., described below with regards to at least FIGS. 5A-5C) to direct the motion of the one or more nozzles 402 and thereby the deposition of the ink material (e.g., electrically conductive ink material).

FIGS. 5A-5C illustrate diagrams of the example, non-limiting chip structure 100 during a third stage of manufacturing in accordance with one or more embodiments described herein. Repetitive description of like elements employed in other embodiments described herein is omitted for the sake of brevity. During the third stage of manufacturing, the one or more interconnects 102 can be further printed onto the one or more chip pads 104 via one or more 3D printing technologies. As a result of the third stage of manufacturing, one or more second portions 102b of the one or more interconnects 102 can be formed on the one or more chip pads 104.

As shown in FIGS. 5A-5C, one or more features of the second stage of manufacturing can be repeated to further print the one or more interconnects 102. For example, the one or more 3D printing technologies can be further executed to deposit ink material (e.g., electrically conductive ink material) onto one or more previously formed portions of the one or more interconnects 102 (e.g., onto at least the first portion 102a of the one or more interconnects 102). By depositing additional ink material onto one or more previously formed portions of the interconnects 102 (e.g., onto first portion 102a), the third stage of manufacturing can further print the one or more interconnects 102 to a desired height (e.g., can further print the one or more interconnects 102 along the Y axis shown in FIGS. 5A and/or 5C).

In various embodiments, the third stage of manufacturing can be repeated multiple times to print the one or more interconnects 102 into a desired geometry and/or height (e.g., along the Y axis of FIGS. 5A and/or 5C). For example, with each implementation of the third stage of manufacturing, additional ink material (e.g., electrically conductive ink material) can be deposited onto previously deposited ink material to further print the one or more interconnects 102. Additionally, each implementation of the third stage of manufacturing can deposit ink material into the same size area, a smaller area, and/or a larger area than one or more previous areas of ink material deposition. For example, each implementation of the third stage of manufacturing can follow the same one or more printing directions or one or more different printing directions.

In one or more embodiments, the one or more 3D printing technologies can continuously deposit the ink material (e.g., electrically conductive ink material) while transitioning from the second stage of manufacturing to the third stage of manufacturing. Likewise, in one or more embodiments the one or more 3D printing technologies can continuously deposit ink material (e.g., electrically conductive ink material) while transitioning from one implementation of the third stage of manufacturing to another implementation of the third stage of manufacturing.

In various embodiments, the 3D printing technology can follow the one or more printing directions (e.g., represented by the “P” arrow) employed during the second stage of manufacturing during one or more implementations of the third stage of manufacturing. In one or more embodiments, the 3D printing technology can follow one or more different printing directions (e.g., represented by the “P” arrow) during one or more implementations of the third stage of manufacturing than the one or more printing directions employed during the second stage of manufacturing. For instance, FIG. 5B depicts an exemplary printing direction (e.g., represented by the “P” arrow) employed during the third stage of manufacturing that is the reverse of the printing direction (e.g., represented by the “P” arrow) employed during the second stage of manufacturing. In another instance, one or more printing directions employed during the third stage of manufacturing can be parallel or orthogonal to one or more printing directions employed during the second stage of manufacturing.

As shown in FIG. 5B, the printing direction (e.g., represented by arrow “P”) employed during the one or more implementations of the third stage of manufacturing can traverse the previously deposited ink material along the X axis, the Z axis, and/or combinations thereof. Further, the printing direction can follow a straight line, a curved line, a wavy line, a combination thereof and/or the like. Thereby, the printing direction (e.g., represented by arrow “P”) can traverse through an area to be occupied by additional portions of the one or more interconnects 102 (e.g., can traverse through an area to be occupied by the one or more second portions 102b). Further, the path of the printing direction (e.g., represented by arrow “P”) can be defined by the geometry of the one or more interconnects 102. Therefore, the location and/or path of the printing direction (e.g., represented by arrow “P”) can be based on the desired geometry of the one or more interconnects 102 at the given height being printed during the given implementation of the third stage of manufacturing. For example, the path of the printing direction (e.g., represented by arrow “P”) shown in FIG. 5B can be employed to heighten the rectangular prism and/or cuboid geometry defined during the second stage of manufacturing shown in FIGS. 5A-5C.

As the nozzle 402 traverses the printing direction (e.g., represented by arrow “P”) during the one or more implementations of the third stage of manufacturing, the ink material (e.g., electrically conductive ink material) can be deposited onto previously deposited ink material. For example, FIG. 5C depicts a second portion 102b of the one or more interconnects 102 formed from the example nozzle 402 traversing the exemplary printing direction (e.g., represented by arrow “P”) shown in FIG. 5B. Additionally, although FIGS. 5A-5C illustrate a continuous, or near continuous, deposition of ink material (e.g., electrically conductive ink material) onto the previously deposited ink material along the printing direction (e.g., represented by arrow “P”); the architecture of the 3D printing is not so limited. For example, embodiments in which the ink material (e.g., electrically conductive ink material) is deposited periodically (e.g., in accordance with one or more scheduled intervals) are also envisaged.

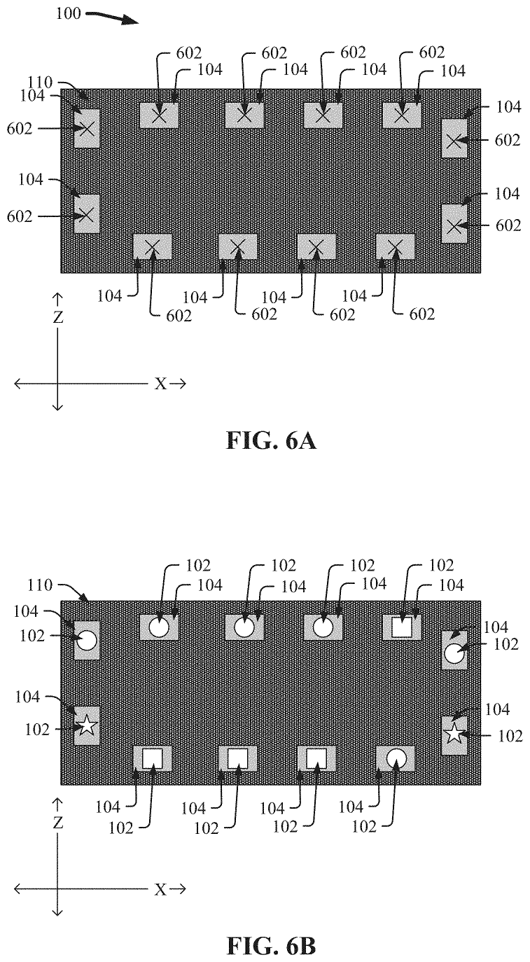

FIGS. 6A-6B illustrate diagrams of example, non-limiting top-down views of a chip to be subject to 3D printing in accordance with one or more embodiments described herein. Repetitive description of like elements employed in other embodiments described herein is omitted for the sake of brevity. As shown in FIGS. 6A-6B, the one or more 3D printing technologies can be employed at multiple locations on a chip and/or a semiconductor device. For example, FIGS. 6A-6B can regard the example chip structure 100 where multiple interconnects 102 are 3D printed onto multiple chip pads 104 (e.g., located on the perimeter of the given chip).

FIG. 6A depicts a top-down view of the chip structure 100 during the first stage of manufacturing. Also shown in FIG. 6A, the first stage of manufacturing can include identifying the location of where the one or more 3D technologies can be employed. For instance, FIG. 6A illustrates the printing locations 602 for the one or more interconnects 102. In one or more embodiments, an entity employing the one or more 3D technologies can identify the printing locations 602 to deposit the ink material by defining the center point of 3D structure to be formed by the one or more 3D printing technologies. For example, a manufacturer of the one or more interconnects 102 can identify one or more printing locations 602 where the center of the one or more interconnects 102 can be positioned as a result of the 3D printing process (e.g., the second and/or third stages of manufacturing). In one or more embodiments, an entity employing the one or more 3D technologies can identify the printing location 602 to deposit the ink material by defining the surface area to be occupied by the 3D printed structures. For example, a manufacturer of the one or more interconnects 102 can identify the boundaries of one or more surface areas on the one or more chip pads 104 where the one or more interconnects 102 are to be printed (e.g., via the second and/or third stages of manufacturing).

In various embodiments, the printing locations 602 can be sent to the one or more computer devices 404, which can be employed to control the one or more 3D printing technologies. For example, 3D printing software on the one or more computer devices 404 can be employed to generate one or more print files that can define the size, shape, and/or geometry of the one or more 3D structures to be printed (e.g., one or more interconnects 102) via the one or more 3D printing technologies (e.g., via the second stage of manufacturing and/or the third stage of manufacturing described herein). For instance, the one or more print files can define the one or more printing directions to be employed during the 3D printing processes. In another instance, the one or more print files can further define the type of ink material to be deposited and/or one or more settings associated with the one or more 3D printing technologies (e.g., pressure settings, flow settings, speed settings, a combination thereof, and/or the like). Further, the one or more print files can be supplemented with the location data defining the printing locations 602 for the one or more 3D printed structures. For instance, printing locations 602 on a given chip can be translated into location data (e.g., coordinate data related to a virtual grid) associated with one or more features defined by the one or more print files generated and/or employed by the one or more computer devices 404.

In one or more embodiments, the one or more 3D printing technologies employed during the second and/or third stage of manufacturing can print the interconnects 102 simultaneously, concurrently, and/or sequentially. For example, a first interconnect 102 (e.g., located on a first chip pad 104) can be printed simultaneously, concurrently, and/or sequentially with a second interconnect 102 (e.g., located on a second chip pad 104). For example, respective nozzles 402 can be employed with regards to the printing of respective interconnects 102 to expedite manufacturing of the chip structure 100. Additionally, as shown in FIG. 6B, one or more first interconnects 102 of a given chip can have a different size and/or geometry than one or more second interconnects 102 of the given chip. For instance, FIG. 6B depicts an example chip structure 100 that includes one or more interconnects 102 having a circular top surface 202, one or more interconnects 102 having a rectangular top surface 202, and/or one or more interconnects 102 having a star shaped top surface 202.

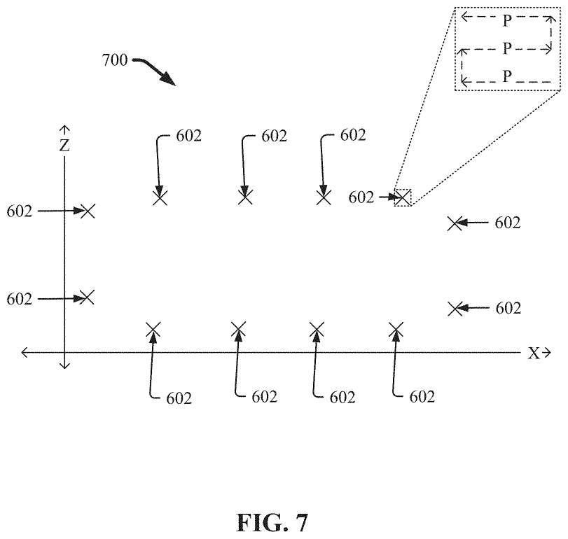

FIG. 7 illustrates a diagram of an example, non-limiting printing map 700 that can be generated to facilitate the execution of one or more 3D printing technologies in accordance with one or more embodiments described herein. Repetitive description of like elements employed in other embodiments described herein is omitted for the sake of brevity. In various embodiments, one or more printing maps 700 can be included in one or more printing files executable by the one or more computer devices 404 to facilitate the 3D printing technologies described herein.

As shown in FIG. 7, the one or more printing maps 700 can delineate the printing locations 602 with regards to coordinates along the Z and/or X axis. For example, the Z and/or X axis can define boundaries of an area available for printing via the one or more printing technologies, where coordinates along the Z and/or X axis can delineate printing locations 602 within the available printing area. For instance, the printing locations 602 depicted in the example printing map 700 shown in FIG. 7 can correspond to the example chip architecture shown in FIGS. 6A-B. Additionally, as shown in FIG. 7, the one or more printing maps 700 can include one or more printing directions associated with one or more printing locations 602. For example, the one or more printing maps 700 can include the printing directions to be employed at each printing location 602. For instance, the printing directions (e.g., represented by P arrows) depicted in the example printing map 700 shown in FIG. 7 can correspond to the example printing directions shown in FIG. 4B. In various embodiments, respective printing locations 602 can be associated with respective printing directions depending on the geometry of the 3D structure (e.g., interconnect 102) to be printed at the printing location 602.

In one or more embodiments, multiple printing maps 700 can be employed by the one or more computer devices 404 to print a 3D structure (e.g., interconnect 102). For example: a first printing map 700 can be employed to delineate printing locations 602 and/or printing directions during the second stage of manufacturing described herein; a second printing map 700 can be employed to delineate printing locations 602 and/or printing directions during the third stage of manufacturing described herein; and one or more additional printing maps 700 can be employed to delineate printing locations 602 and/or printing directions during additional iterations of the third stage of manufacturing.

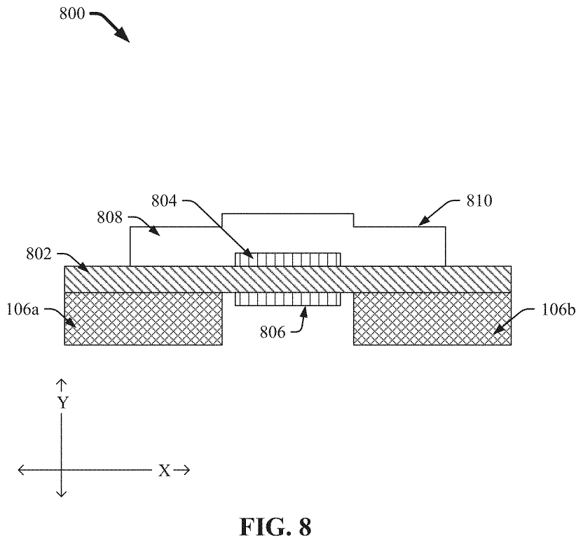

FIG. 8 illustrates a diagram of an example, non-limiting resonator architecture 800 that can include one or more tuning layers 808 printed via the one or more printing technologies described herein. Repetitive description of like elements employed in other embodiments described herein is omitted for the sake of brevity. In various embodiments, the resonator architecture 800 can be included on one or more chips of flip chip assembly (e.g., the example flip chip assembly 112). For example, the resonator architecture 800 can be comprised within a balk acoustic wave device.

As shown in FIG. 8, the resonator architecture 800 can comprise one or more piezoelectric layers 802 positioned on a semiconductor substrate 106. Example types of material that can be comprised within the one or more piezoelectric layers 802 can include, but are not limited to: zinc oxide, cadmium sulfide, cadmium selenide, aluminum nitride, aluminum scandium nitride (e.g., with varying aluminum to scandium ratios), lithium niobate, lead titanate, a combination thereof, and/or the like. In various embodiments, the one or more piezoelectric layers 802 can have a thickness (e.g., along the “Y” axis shown in FIG. 8) ranging from, for example, greater than or equal to 0.03 μm and less than or equal to 10 μm. Additionally, the resonator architecture 800 can comprise a first electrode 804 and/or a second electrode 806 positioned adjacent to the one or more piezoelectric layers 802. For example, the first electrode 804 can be positioned on top of the one or more piezoelectric layers 802 along the “Y” axis shown in FIG. 8, and the second electrode 806 can be positioned below the one or more piezoelectric layers 802 along the “Y” axis (e.g., as shown in FIG. 8). In various embodiments, the first electrode 804 can be in contact with a first surface of the one or more piezoelectric layers 802, and the second electrode 806 can be in contact with a second surface (e.g., opposite the first surface) of the one or more piezoelectric layers 802 (e.g., as shown in FIG. 8). Further, the first electrode 804 and the second electrode 806 can have substantially the same composition or different compositions. Example materials that can be comprised within the first electrode 804 and/or the second electrode 806 can include, but are not limited to: molybdenum, aluminum, tungsten, a combination thereof, and/or the like.

In one or more embodiments, the semiconductor substrate 106 can comprise a first semiconductor substrate portion 106a and a second semiconductor substrate portion 106b, which can be spaced apart from each other. Further, the second electrode 806 can be positioned between the first semiconductor substrate portion 106a and the second semiconductor substrate portion 106b (e.g., as shown in FIG. 8). In one or more embodiments, the one or more piezoelectric layers 802 can generate an internal electrical charge from an applied mechanical stress and deliver the electrical charge to the first electrode 804 and/or second electrode 806. For example, the resonator architecture 800 can generate an oscillating signal of a defined frequency in response to resonant mechanical vibrations.

In various embodiments, the operating frequency of the resonator architecture 800 can be tuned via one or more tuning layers 808 that can be printed onto the first electrode 804 and/or one or more piezoelectric layers 802 via one or more 3D printing technologies in accordance with the printing techniques employed to form the one or more interconnects 102 described herein. For instance, the one or more tuning layers 808 can be comprised of an ink material compatible with one or more 3D printing technologies described herein. Example ink material that can be comprised within the one or more tuning layers 808 can include, but are not limited to: gold, aluminum, copper, tantalum, cobalt, ruthenium, titanium, tin, silver, solder material, an alloy thereof, a combination thereof, and/or the like. In various embodiments, the one or more tuning layers 808 can be printed onto: solely the first electrode 804, solely the one or more piezoelectric layers 802, or a combination of at least a portion of the first electrode 804 and at least a portion of the one or more piezoelectric layers 802 (e.g., as shown in FIG. 8).

The one or more tuning layers 808 can have a thickness (e.g., along the “Y” axis shown in FIG. 8) ranging from, for example, greater than or equal to 0.01 μm and less than or equal to 20 μm. In various embodiments, the one or more tuning layers 808 can have a substantially uniform thickness (e.g., as shown in FIG. 8). Alternatively, the one or more tuning layers 808 can comprise multiple portions with respective thicknesses (e.g., thicker, or thinner portions). Additionally, an upper surface 810 of the one or more tuning layers 808 can have a variety of geometries depending on the desired operating frequency of the resonator architecture 800. For example, the upper surface 810 of the one or more tuning layers 808 can have circular and/or polygonal geometries (e.g., such as the geometries for the top surface 202 of the one or more interconnects 102 shown in FIG. 2). In various embodiments, the shape of the upper surface 810 can affect the amount of ink material comprised within the one or more tuning layers 808.

As ink material is printed onto the first electrode 804 and/or one or more piezoelectric layers 802 to form the one or more tuning layers 808, the presence of the ink material can alter the operating frequency of the resonator architecture 800. Thereby, the composition, location, dimensions, and/or geometry of the one or more tuning layers 808 can affect the operating frequency of the resonator architecture 800. Additionally, the composition, location, dimensions, and/or geometry can be selected to achieve a target operating frequency for the resonator architecture 800. For example, as more ink material is deposited onto the one or more piezoelectric layers 802 and/or first electrode 804 to form the one or more tuning layers 808, the operating frequency of the resonator architecture 800 can increase. Various embodiments described herein can be employed to individually tune respective resonator architectures 800 of a semiconductor device; thereby combinations of resonator architectures 800 can form filters tuned to achieve a desired centre frequency and/or bandwidth.

While FIG. 8 depicts an example resonator architecture 800 embodied as a film bulk acoustic wave resonator (“FBAR”), where the one or more piezoelectric layers 802 can be suspended by an air-bridge between the first semiconductor substrate portion 106a and the second semiconductor substrate portion 106b; the structure of the resonator architecture 800 is not so limited. For example, the resonator architecture 800 can also be embodied as a solidly mounted resonator (“SMR”), where the one or more piezoelectric layers 802 can be positioned onto one or more stacks of alternating layers of low impedance materials and high impedance materials, which can be positioned on the semiconductor substrate 106. Further, the one or more stacks can be built on a Bragg reflector basis and exhibit an acoustic mirror behavior. For instance, the one or more stacks of alternating layers can comprise quarter wavelength layers serving as a reflector to keep acoustic waves confined near the one or more piezoelectric layers 802. The number of alternating layers within the one or more stacks can depend on the mechanical impedances between layers and/or the semiconductor substrate 106 as well as an analysis of the resonance response as a function of the number of layers versus the resonator Q and coupling coefficient. Where the resonator architecture 800 embodies the SMR structure, the one or more tuning layers 808 can still be positioned on the one or more piezoelectric layers 802 and/or first electrodes 804 in accordance with the various embodiments described herein.

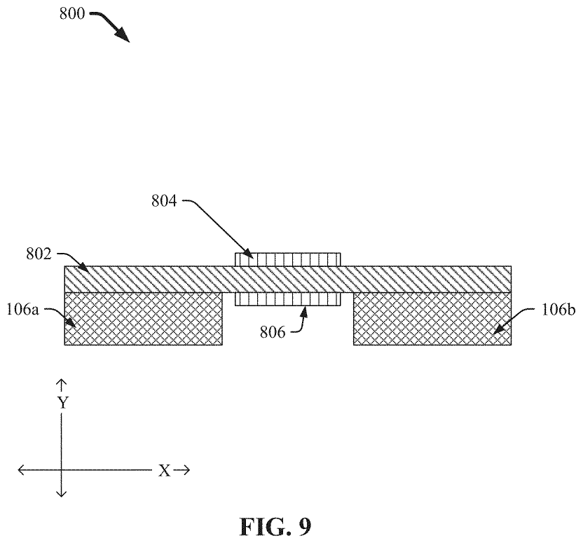

FIG. 9 illustrates a diagram of the example, non-limiting resonator architecture 800 during a first stage of tuning in accordance with one or more embodiments described herein. Repetitive description of like elements employed in other embodiments described herein is omitted for the sake of brevity. During the first stage of tuning, the untuned resonator architecture 800 can be provided and/or prepared for subsequent printing of the one or more tuning layers 808. For example, prior to being tuned, the resonator architecture 800 can comprise the semiconductor substrate 106, one or more piezoelectric layers 802, first electrode 804, and/or second electrode 806 absent the one or more tuning layers 808. In various embodiments, the resonator architecture 800 can be operated during the first stage of tuning to determine the initial operating frequency. Based on the initial operating frequency, the amount of ink material to be added (e.g., via one or more the second and/or third stages of tuning described herein) can be determined to achieve a target operating frequency.

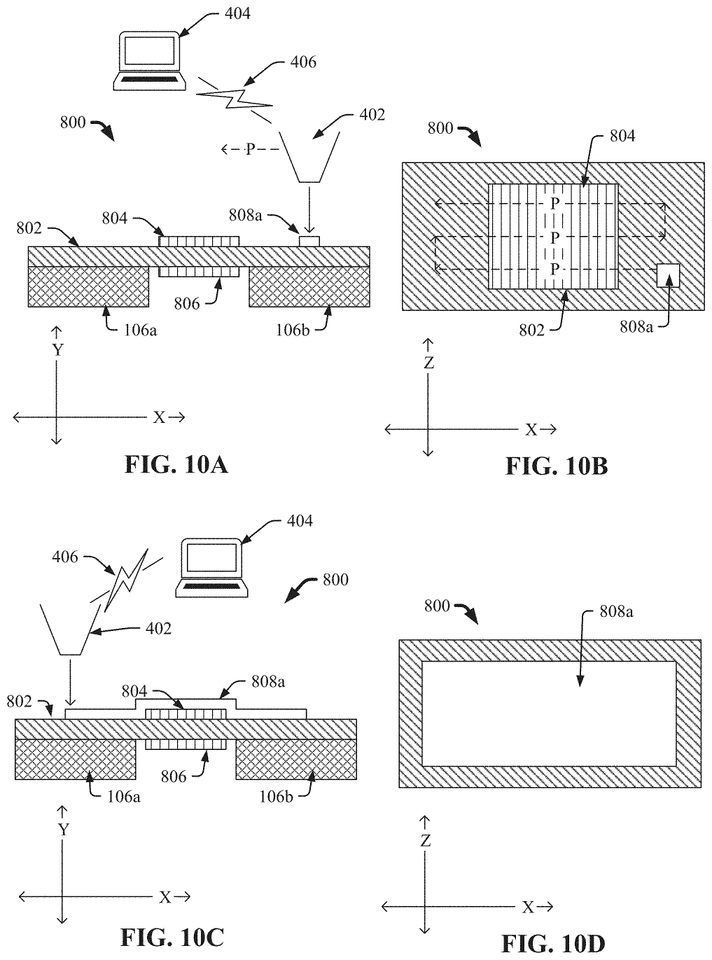

FIGS. 10A-10D illustrate diagrams of the example, non-limiting resonator architecture 800 during a second stage of tuning in accordance with one or more embodiments described herein. Repetitive description of like elements employed in other embodiments described herein is omitted for the sake of brevity. During the second stage of tuning, the one or more tuning layers 808 can be printed onto the one or more piezoelectric layers 802 and/or first electrode 804 via one or more 3D printing technologies. As a result of the second stage of tuning, at least a first section 808a of the one or more tuning layers 808 can be formed on the one or more piezoelectric layers 802 and/or first electrode 804.

In various embodiments, the 3D printing technologies can deposit ink material (e.g., metal material) of the one or more tuning layers 808 onto the one or more piezoelectric layers 802 and/or first electrode 804. For instance, the one or more 3D printing technologies can print the one or more tuning layers 808 via an additive process, where ink material (e.g., electrically conductive ink material) can be deposited via successive layers positioned on top of each other repetitively until the desired 3D shape is achieved. Example 3D printing technologies that can be employed to print the one or more interconnects 102 can include, but are not limited to: a direct write printing technology, an inkjet printing technology, an aerosol jet printing technology, a combination thereof, and/or the like.

For example, FIGS. 10A and 10C depict the example nozzle 402 of the 3D printing technology. The ink material (e.g., metal material) that comprises the one or more tuning layers 808 can be expelled from the nozzle 402 when executing the 3D printing technology. For instance, FIGS. 10A and 10C depict ink material (e.g., metal material) being expelled from the example nozzle 402 and onto the one or more piezoelectric layers 802 and/or first electrode 804. As shown in FIGS. 10A-10B, the example nozzle 402 can travel along a printing direction (e.g., represented by arrow “P” in FIGS. 10A-10B) in accordance with various embodiments described herein. As the example nozzle 402 travels along the printing direction (e.g., represented by arrow “P”), the nozzle 402 can also be depositing the ink material (e.g., metal ink material) onto the one or more piezoelectric layers 802 and/or first electrode 804.

FIG. 10A depicts the nozzle 402 at a first position above the one or more piezoelectric layers 802 during execution of the 3D printing technology. From the first position, the nozzle 402 can move along the printing direction (e.g., represented by arrow “P”) to a second position depicted in FIG. 10C. As shown in FIG. 10B, the printing direction (e.g., represented by arrow “P”) can traverse the one or more piezoelectric layers 802 and/or first electrode 804 along the X axis, the Z axis, and/or combinations thereof. Further, the printing direction can follow a straight line, a curved line, a wavy line, a combination thereof and/or the like. Thereby, the printing direction (e.g., represented by arrow “P”) can traverse through an area to be occupied by the one or more tuning layers 808. Further, the path of the printing direction (e.g., represented by arrow “P”) can be defined by the geometry of the one or more tuning layers 808. Therefore, the location and/or path of the printing direction (e.g., represented by arrow “P”) can be based on the desired geometry of the one or more tuning layers 808. For example, the path of the printing direction (e.g., represented by arrow “P”) shown in FIG. 10B can be employed to print a rectangular prism and/or cuboid geometry of the one or more tuning layers 808.

As the nozzle 402 traverses the printing direction (e.g., represented by arrow “P”), the ink material (e.g., metal ink material) can be deposited onto the one or more piezoelectric layers 802 and/or first electrode 804. For example, FIGS. 10C-10D depict the first section 808a of the one or more tuning layers 808 formed from the example nozzle 402 traversing the exemplary printing direction (e.g., represented by arrow “P”) shown in FIG. 10B. Additionally, although FIGS. 10C-10D illustrate a continuous, or near continuous, deposition of ink material (e.g., electrically conductive ink material) onto the chip pad 104 along the printing direction (e.g., represented by arrow “P”); the architecture of the 3D printing is not so limited. For example, embodiments in which the ink material (e.g., metal ink material) is deposited periodically (e.g., in accordance with one or more scheduled intervals) are also envisaged.

In various embodiments, the one or more example nozzles 402 of the one or more printing technologies can be controlled via the one or more computer devices 404 via one or more communication connections 406 (e.g., direct electrical connections and/or wireless connections) in accordance with the various embodiments described herein. For instance, the one or more computer devices 404 can send data and/or otherwise control equipment of the one or more 3D printing technologies to define the type of ink material to be used and/or the one or more printing directions to be traversed by the nozzle 402. In various embodiments, the one or more computer devices 404 can execute 3D printing software to define one or more printing directions that can be employed during the tuning of a resonator architecture 800 (e.g., described below with regards to at least FIGS. 10A-10C) to direct the motion of the one or more nozzles 402 and thereby the deposition of the ink material (e.g., metal ink material).

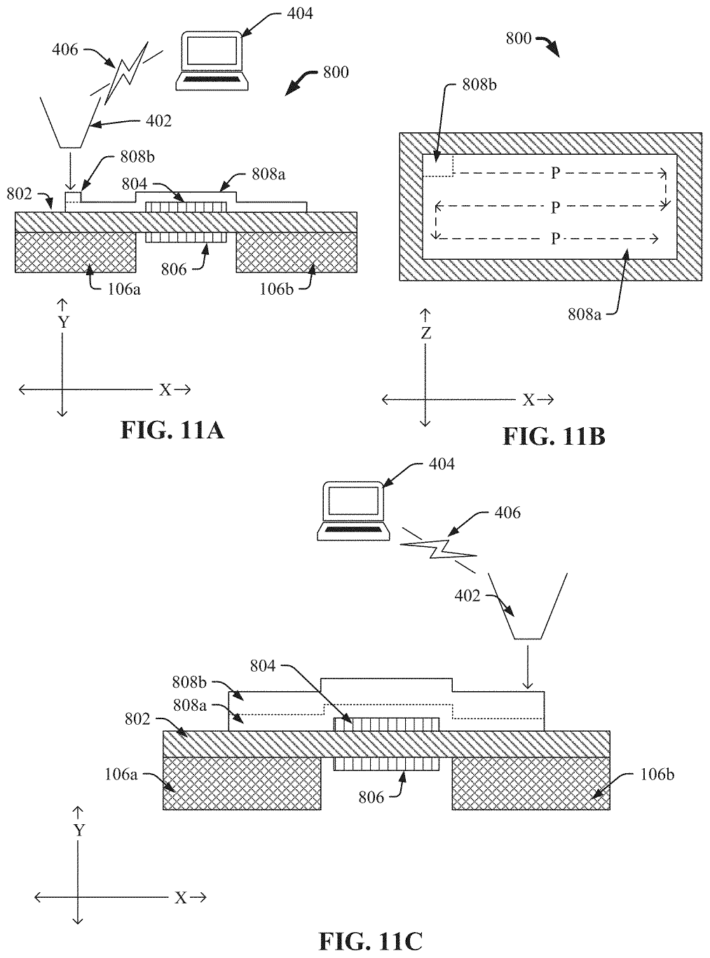

FIGS. 11A-11C illustrate diagrams of the example, non-limiting resonator architecture 800 during a third stage of tuning in accordance with one or more embodiments described herein. Repetitive description of like elements employed in other embodiments described herein is omitted for the sake of brevity. During the third stage of tuning, the one or more tuning layers 808 can be further printed onto the one or more piezoelectric layers 802 and/or first electrode 804 via one or more 3D printing technologies. As a result of the third stage of tuning, one or more second section 808b of the one or more tuning layers 808 can be formed.

As shown in FIGS. 11A-11C, one or more features of the second stage of tuning can be repeated to further print the one or more tuning layers 808. For example, the one or more 3D printing technologies can be further executed to deposit ink material (e.g., metal ink material) onto one or more previously formed portions of the one or more tuning layers 808 (e.g., onto at least the first section 808a of the one or more tuning layers 808). By depositing additional ink material onto one or more previously formed portions of the tuning layers 808 (e.g., onto first section 808a of the tuning layers 808), the third stage of tuning can further print the one or more tuning layers 808 to a desired height (e.g., can further print the one or more tuning layers 808 along the Y axis shown in FIGS. 11A and/or 11C).

In various embodiments, the third stage of tuning can be repeated multiple times to print the one or more tuning layers 808 into a desired geometry and/or height (e.g., along the Y axis of FIGS. 11A and/or 11C). For example, with each implementation of the third stage of tuning, additional ink material (e.g., metal ink material) can be deposited onto previously deposited ink material to further print the one or more tuning layers 808. Additionally, each implementation of the third stage of tuning can deposit ink material into the same size area, a smaller area, and/or a larger area than one or more previous areas of ink material deposition. For example, each implementation of the third stage of tuning can follow the same one or more printing directions or one or more different printing directions.

In one or more embodiments, the one or more 3D printing technologies can continuously deposit the ink material (e.g., metal ink material) while transitioning from the second stage of tuning to the third stage of tuning. Likewise, in one or more embodiments the one or more 3D printing technologies can continuously deposit ink material (e.g., metal ink material) while transitioning from one implementation of the third stage of tuning to another implementation of the third stage of tuning.

In various embodiments, the 3D printing technology can follow the one or more printing directions (e.g., represented by the “P” arrow) employed during the second stage of tuning during one or more implementations of the third stage of tuning. In one or more embodiments, the 3D printing technology can follow one or more different printing directions (e.g., represented by the “P” arrow) during one or more implementations of the third stage of tuning than the one or more printing directions employed during the second stage of tuning. For instance, FIG. 11B depicts an exemplary printing direction (e.g., represented by the “P” arrow) employed during the third stage of tuning that is the reverse of the printing direction (e.g., represented by the “P” arrow) employed during the second stage of tuning. In another instance, one or more printing directions employed during the third stage of manufacturing can be parallel or orthogonal to one or more printing directions employed during the second stage of tuning.

As shown in FIG. 11B, the printing direction (e.g., represented by arrow “P”) employed during the one or more implementations of the third stage of tuning can traverse the previously deposited ink material along the X axis, the Z axis, and/or combinations thereof. Further, the printing direction can follow a straight line, a curved line, a wavy line, a combination thereof and/or the like. Thereby, the printing direction (e.g., represented by arrow “P”) can traverse through an area to be occupied by additional portions of the one or more tuning layers 808 (e.g., can traverse through an area to be occupied by the one or more second portions 102b). Further, the path of the printing direction (e.g., represented by arrow “P”) can be defined by the geometry of the one or more tuning layers 808. Therefore, the location and/or path of the printing direction (e.g., represented by arrow “P”) can be based on the desired geometry of the one or more tuning layers 808 at the given height being printed during the given implementation of the third stage of manufacturing. For example, the path of the printing direction (e.g., represented by arrow “P”) shown in FIG. 11B can be employed to heighten the rectangular prism and/or cuboid geometry defined during the second stage of tuning shown in FIGS. 11A-11C.

As the nozzle 402 traverses the printing direction (e.g., represented by arrow “P”) during the one or more implementations of the third stage of tuning, the ink material (e.g., metal ink material) can be deposited onto previously deposited ink material. For example, FIG. 11C depicts a second section 808b of the one or more tuning layers 808 formed from the example nozzle 402 traversing the exemplary printing direction (e.g., represented by arrow “P”) shown in FIG. 11B. Additionally, although FIGS. 11A-11C illustrate a continuous, or near continuous, deposition of ink material (e.g., metal ink material) onto the previously deposited ink material along the printing direction (e.g., represented by arrow “P”); the architecture of the 3D printing is not so limited. For example, embodiments in which the ink material (e.g., metal ink material) is deposited periodically (e.g., in accordance with one or more scheduled intervals) are also envisaged.

In various embodiments, one or more printing maps 700 can be employed by the one or more computer devices 404 to facilitate tuning the resonator architecture 800. For example, a semiconductor device (e.g., a monolithic microwave integrated circuit (“MMIS”), such as a bulk acoustic wave device) comprise one or more resonator architectures 800, where one or more printing maps 700 can delineate printing locations 602 corresponding to one or more of the resonator architectures 800 to be tuned on the semiconductor device. Further, the one or more printing maps 700 can delineate one or more printing directions to be employed to form the one or more tuning layers 808 during the tuning (e.g., in accordance with one or more iterations of the second and/or third stages of tuning described herein). In accordance with various embodiments described herein, multiple printing maps 700 can be generated and/or employed by the one or more computer devices 404 to facilitate the second and/or third stage of tuning.

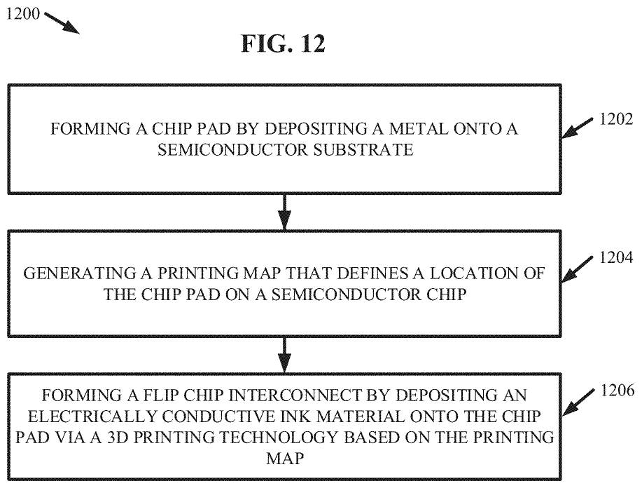

FIG. 12 illustrates a flow diagram of an example, non-limiting method 1200 that can facilitate the manufacturing of one or more 3D printed flip chip interconnects 102 in accordance with one or more embodiments described herein. Repetitive description of like elements employed in other embodiments described herein is omitted for the sake of brevity.

At 1202, the method 1200 can comprise forming one or more chip pads 104 by depositing a metal onto a semiconductor substrate 106. For example, formation of the one or more chip pads 104 at 1202 can be performed in accordance with the first stage of manufacturing described herein. At 1204, the method 1200 can comprise generating one or more printing maps 700 that can define one or more locations of the one or more chip pads 104 (e.g., printing locations) on a semiconductor chip. Additionally, the one or more printing maps 700 can define one or more printing directions to be utilized during execution of one or more 3D printing technologies. In various embodiments, one or more entities can employ one or more computer devices 404 to facilitate the generation and/or employment of the one or more printing maps 700 generated at 1204. For example, generating the one or more printing maps 700 at 1204 can be performed during the first stage of manufacturing described herein in preparation for the second and/or third stage of manufacturing described herein. Additionally, generation of the one or more printing maps 700 at 1204 can include one or more features described herein with regards to at least FIGS. 6A-7.

At 1206, the method 1200 can comprise forming one or more flip chip interconnects 102 by depositing an electrically conductive ink material onto the one or more flip chip pads 104 via one or more 3D printing technologies based on the one or more printing maps 700. In accordance with various embodiments described herein, the one or more 3D printing technologies can be employed (e.g., via one or more computer devices 404) to print the electrically conductive ink material onto the one or more chip pads 104 to build the one or more interconnects 102 into three dimensional structures with defined shapes, geometries, and/or dimensions. For example, forming the one or more interconnects 102 at 1206 can be performed in accordance with one or more iterations of the second and/or third stages of manufacturing described herein.

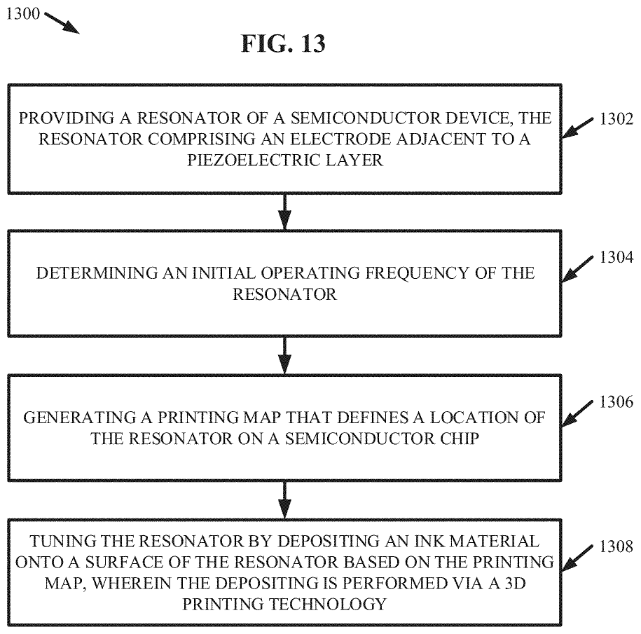

FIG. 13 illustrates a flow diagram of an example, non-limiting method 1300 that can facilitate the tuning of one or more resonator architectures 800 via one or more 3D printing technologies in accordance with one or more embodiments described herein. Repetitive description of like elements employed in other embodiments described herein is omitted for the sake of brevity.

At 1302, the method 1300 can comprise providing one or more resonators of a semiconductor device (e.g., resonator architectures 800), where the one or more resonators can comprise one or more electrodes adjacent to one or more piezoelectric layers 802. For example, the one or more resonators provided at 1302 can embody the resonator architecture 800 described herein. At 1304, the method 1300 can comprise determining an initial operating frequency of the one or more resonators (e.g., resonator architectures 800). For example, the one or more resonators can be operated during the first stage of tuning described herein to measure the resonators' initial operating frequency.

At 1306, the method 1300 can comprise generating one or more printing maps 700 that can define one or more locations of the one or more resonators (e.g., resonator architectures 800) on a semiconductor chip. Additionally, the one or more printing maps 700 can define one or more printing directions to be utilized during execution of one or more 3D printing technologies. In various embodiments, one or more entities can employ one or more computer devices 404 to facilitate the generation and/or employment of the one or more printing maps 700 generated at 1306. For example, generating the one or more printing maps 700 at 1306 can be performed during the first stage of tuning described herein in preparation for the second and/or third stage of tuning described herein.

At 1308, the method 1300 can comprise tuning the one or more resonators (e.g., resonator architectures 800) by depositing an ink material (e.g., compatible with 3D printing technologies) onto a surface of the one or more resonators based on the one or more printing maps 700, where the depositing can be performed via one or more 3D printing technologies. For example, the ink material can be printed onto one or more piezoelectric layers 802 and/or electrodes (e.g., first electrode 804) of the one or more resonators (e.g., resonator architectures 800) via the one or more 3D printing technologies. For instance, the depositing at 1308 can be performed in accordance with the one or more iterations of the second and/or third stage of tuning described herein. In various embodiments, depositing the ink material onto the one or more resonators can alter the operating frequency of the resonators from the initial operating frequency to a target operating frequency. For example, as the ink material is added to the one or more resonators, the operating frequency of the one or more resonators can increase.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

It is, of course, not possible to describe every conceivable combination of components, products and/or methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device, comprising:
a three-dimensionally printed flip chip interconnect that includes an electrically conductive ink material that is compatible with a three-dimensional printing technology, the three-dimensionally printed flip chip interconnect located on a metal surface of a semiconductor chip.

2. The semiconductor device of claim 1, wherein the three-dimensional printing technology is a direct write printing technology, an inkjet printing technology, or an aerosol jet printing technology.

3. The semiconductor device of claim 1, wherein the electrically conductive ink material comprises at least one member selected from the group consisting of gold, aluminum, copper, tantalum, cobalt, ruthenium, titanium, tin, silver, solder, or an alloy thereof,

4. The semiconductor device of claim 3, wherein the three-dimensionally printed flip chip interconnect has a cylindrical shape.

5. The semiconductor device of claim 1, wherein the metal surface is a chip pad comprising at least one metal selected from the group consisting of gold, aluminum, copper, tungsten, tantalum, silver, and palladium.

6. The semiconductor device of claim 1, wherein the semiconductor device is an integrated circuit device.

7. The semiconductor device of claim 1, wherein the three-dimensionally printed flip chip interconnect further includes a second electrically conductive ink material that is also compatible with the three-dimensional printing technology.

8. The semiconductor device of claim 1, wherein a distal end of the three-dimensionally printed flip chip interconnect has a polygon shaped surface.

9. A method of fabricating a semiconductor, comprising:
forming a flip chip interconnect by depositing an electrically conductive ink material onto a chip pad of a semiconductor device, wherein the depositing is performed via a three-dimensional printing technology.

10. The method of claim 9, further comprising:
forming the chip pad by depositing a metal onto a semiconductor substrate, wherein the metal comprises at least one member from the group consisting of gold, aluminum, copper, tungsten, tantalum, silver, and palladium.

11. The method of claim 10, further comprising:
generating a printing map that defines a location of the chip pad on a semiconductor chip, wherein the electrically conductive ink material is deposited via the three-dimensional printing technology based on the printing map.

12. The method of claim 9, wherein the electrically conductive ink material comprises at least one member selected from the group consisting of gold, aluminum, copper, tantalum, cobalt, ruthenium, titanium, tin, silver, or an alloy thereof.

13. The method of claim 9, wherein the three-dimensional printing technology is a direct write printing technology, an inkjet printing technology, or an aerosol jet printing technology.

14. The method of claim 9, wherein the semiconductor device is an integrated circuit.

15. A method of processing a semiconductor, comprising:
tuning a resonator of a semiconductor device by depositing an ink material onto a surface of the resonator, wherein the depositing is performed via a three-dimensional printing technology.

16. The method of claim 15, further comprising:
providing a resonator, the resonator comprising an electrode adjacent to a piezoelectric layer, wherein the ink material is deposited onto at least one of: the electrode, and the piezoelectric layer.

17. The method of claim 16, further comprising:
generating a printing map that defines a location of the resonator on a semiconductor chip, wherein the ink material is deposited via the three-dimensional printing technology based on the printing map.

18. The method of claim 15, wherein the ink material comprises at least one member selected from the group consisting of gold, aluminum, copper, tantalum, cobalt, ruthenium, titanium, tin, silver, or an alloy thereof.

19. The method of claim 15, wherein the three-dimensional printing technology is a direct write printing technology, an inkjet printing technology, or an aerosol jet printing technology.

20. The method of claim 15, wherein the semiconductor device is an integrated circuit.
